(19) United States
(12) Patent Application Publication
(10) Pub. No.: US 2015/0002176 A1
(43) Pub. Date: Jan. 1, 2015

(54) TOUCH SENSING DEVICE AND TOUCHSCREEN APPARATUS

(71) Applicant: SAMSUNG ELECTRO-MECHANICS CO., LTD., Suwon (KR)

(72) Inventors: Yong Il Kwon, Suwon (KR); Tah Joon Park, Suwon (KR); Byeong Hak Jo, Suwon (KR)

(73) Assignee: SAMSUNG ELECTRO-MECHANICS CO., LTD., Suwon (KR)

(21) Appl. No.: 14/019,694

(22) Filed: Sep. 6, 2013

(30) Foreign Application Priority Data
Jun. 28, 2013 (KR) 10-2013-0076028

(51) Int. Cl. G01R 27/26

(52) U.S. Cl. CPC G01R 27/2605
USPC 324/679

(57) ABSTRACT

There are provided a touch sensing device and a touchscreen apparatus. The touch sensing device includes: a node capacitor; a self-capacitor disposed between one terminal of the node capacitor and a ground; a driving circuit applying predetermined driving signals to the node capacitor and the self-capacitor; and a sensing circuit unit integrating electrical charges charged in the node capacitor and the self-capacitor, wherein the driving circuit unit applies predetermined driving signals to the node capacitor and the self-capacitor in different periods.

### CROSS-REFERENCE TO RELATED APPLICATIONS

This application claims the priority of Korean Patent Application No. 10-2013-0076028 filed on Jun. 28, 2013, in the Korean Intellectual Property Office, the disclosure of which is incorporated herein by reference.

### BACKGROUND OF THE INVENTION

1. Field of the Invention

The present invention relates to a touch sensing device and a touchscreen apparatus capable of detecting mutual-capacitance and self-capacitance.

2. Description of the Related Art

A touch sensing device such as a touchscreen, a touchpad, or the like, a data input apparatus attached to a display apparatus to provide an intuitive data input method to a user, has recently been widely used in various electronic devices such as cellular phones, personal digital assistants (PDAs), navigation devices, and the like. Particularly, as demand for smartphones has recently increased, a touch sensing device capable of providing various input methods in a limited form factor has increasingly been employed.

A touchscreen used in a portable device may largely be classified as a resistive type touchscreen or a capacitive type touchscreen, according to a method of sensing a touch utilized thereby. Here, the capacitive type touchscreen has advantages, in that it has a relatively long lifespan and may easily allow for various data input methods and gestures to be implemented, such that the use thereof has continuously increased. Particularly, the capacitive type touchscreen may more easily implement a multi-touch interface as compared with the resistive type touchscreen, such that it is widely used in devices such as smartphones, and the like.

The capacitive type touchscreen includes a plurality of electrodes having a predetermined pattern and defining a plurality of nodes in which changes in capacitance are generated by a touch. In the plurality of nodes distributed on a two-dimensional plane, a change in self-capacitance or mutual-capacitance is generated by a touch. Coordinates of the touch may be calculated by applying a weighted average method, or the like, to the change in capacitance generated in the plurality of nodes. Compared to a touchscreen detecting changes in mutual-capacitance, a touchscreen detecting changes in self-capacitance is disadvantageous, in that it cannot recognize multiple touches and may recognize ghost touches; however, it is highly sensitive so as to be able to efficiently recognize a hovering touch, a capability which has recently been required in touchscreen devices. Accordingly, a touchscreen capable of detecting both changes in both mutual-capacitance and self-capacitance is required.

### RELATED ART DOCUMENT

(Patent Document 1) US Patent Publication No. 8,358,142

### SUMMARY OF THE INVENTION

An aspect of the present invention provides a touch sensing device and a touchscreen apparatus capable of selectively detecting changes in self-capacitance and mutual capacitance.

According to an aspect of the present invention, there is provided a touch sensing device including: a node capacitor; a self-capacitor disposed between one terminal of the node capacitor and a ground; a driving circuit unit applying predetermined driving signals to the node capacitor and the self-capacitor; and a sensing circuit unit integrating electrical charges charged in the node capacitor and the self-capacitor, wherein the driving circuit unit applies the driving signals to the node capacitor and the self-capacitor in different periods.

The driving circuit unit may include: a first switch disposed between a supply voltage terminal and the other terminal of the node capacitor; a second switch disposed between the other terminal of the node capacitor and the ground; and a third switch disposed between a connection node of the node capacitor and the self-capacitor, and the supply voltage terminal.

The first and second switches and the third switch may operate during different periods.

The first and second switches may operate according to clock signals having a phase difference of 180 degree.

The sensing circuit unit may discharge a portion of an electrical charge charged in the self-capacitor and then integrates the remainder of the electrical charge.

The sensing circuit unit may include: an integrating circuit including an operational amplifier having a non-inverted terminal connected to the ground, and a feedback capacitor disposed between an output terminal and an inverted terminal of the operational amplifier; a fourth switch disposed between the connection node of the node capacitor and the self-capacitor, and the inverted terminal of the operational amplifier; a fifth switch having one terminal connected to the connection node of the node capacitor and the self-capacitor; and a current source, wherein the other terminal of the fifth switch is connected to the current source or to the ground, or is floated.

The node capacitor may be formed at an intersection between electrodes of a capacitive type touchscreen panel, and the self-capacitor may be formed by the electrodes of the touchscreen panel.

According to another aspect of the present invention, there is provided a touchscreen apparatus including: a plurality of first electrodes extending in a first axial direction; a plurality of second electrodes extending in a second axial direction perpendicular to the first axial direction so as to form a plurality of intersections; and a control unit applying predetermined first driving signals to the plurality of first electrodes to detect changes in mutual-capacitance generated in the plurality of intersections, and applying predetermined second driving signals to the plurality of second electrodes to detect changes in self-capacitance generated in the plurality of second electrodes themselves, wherein the control unit detects changes in the mutual-capacitance and the self-capacitance indifferent periods.

The control unit may include: a driving circuit unit applying predetermined driving signals to each of the pluralities of first and second electrodes; and a sensing circuit unit connected to the plurality of second electrodes, the sensing circuit unit detecting changes in mutual-capacitance generated in a plurality of intersections between the pluralities of first and second electrodes and detecting changes in self-capacitance generated in the plurality of second electrodes.

The driving circuit unit may apply the driving signals to the pluralities of first and second electrodes during different periods.

The driving circuit unit may apply different driving signals to the pluralities of first and second electrodes.

The sensing circuit unit may integrate the mutual- and self-capacitance to create an analog signal.

The sensing circuit unit may discharge a portion of capacitance of the self-capacitor and then integrate the rest of the capacitance.

The control unit may further include: a signal converting unit converting an output signal from the sensing circuit unit into a digital signal; and a calculating unit determining a touch based on the digital signal.

The calculation unit may determine at least one coordinate of coordinates of the touch, a gesture operation and the number of touch.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view illustrating an appearance of an electronic apparatus including a touch sensing device according to an embodiment of the present invention;

FIG. 2 is a view of a panel part included in a touch sensing device according to an embodiment of the present invention;

FIG. 3 is a cross-sectional view of the panel part shown in FIG. 2;

FIG. 4 is a block diagram of a touch sensing device according to an embodiment of the present invention;

FIG. 5 is a circuit diagram of a touch sensing device according to an embodiment of the present invention;

FIG. 6 is a graph illustrating clock signals applied to a switch included in a touch sensing device according to an embodiment of the present invention; and

FIG. 7 is a view schematically illustrating a touchscreen apparatus including a touch sensing device according to an embodiment of the present invention.

### DETAILED DESCRIPTION OF THE INVENTION

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

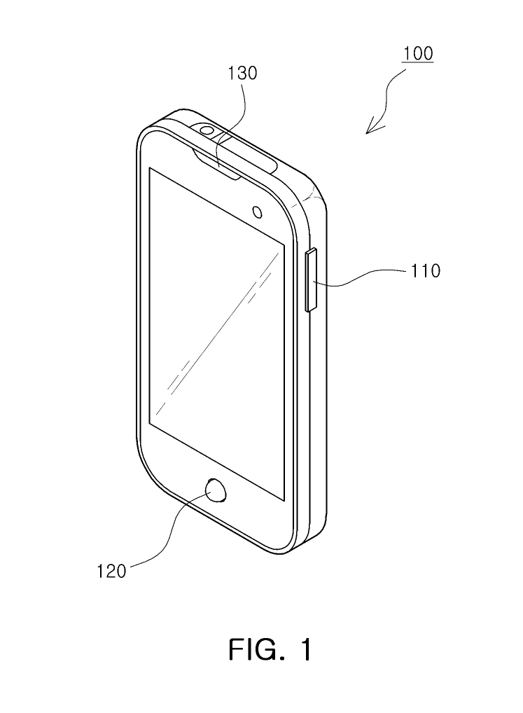

FIG. 1 is a perspective view of an electronic apparatus including a touch sensing device according to an embodiment of the present invention.

Referring to FIG. 1, the electronic apparatus 100 according to the present embodiment may include a display device 110 outputting images on a screen, an input unit 120, an audio unit 130 outputting audio, and a touch sensing device integrated with the display device 110.

As shown in FIG. 1, typically in mobile devices, the touch sensing device is integrated with the display device, and should have a high enough degree of light transmissivity that images on the display can be transmitted therethrough. Therefore, the touch sensing device may be implemented by forming a electrode using a transparent and electrically conductive material such as indium tin oxide (ITO), indium zinc oxide (IZO), zinc oxide (ZnO), carbon nanotubes (CNT), or graphene on a base substrate formed of a transparent film material such as polyethylene telephtalate (PET), polycarbonate (PC), polyethersulfone (PES), polyimide (PI), or the like. The display apparatus may include a wiring pattern disposed in a bezel region thereof, wherein the wiring pattern is connected to the electrode formed of the transparent and conductive material. Since the wiring pattern is visually shielded by the bezel region, it may be formed of a metal such as silver (Ag), copper (Cu), or the like.

Since the touch sensing device according to the embodiment of the present invention is operated in a capacitive manner, the touchscreen apparatus may include a plurality of electrodes having a predetermined pattern. Further, the touch sensing device may include a capacitance sensing circuit to sense a change in the capacitance generated in the plurality of electrodes, an analog-digital converting circuit to convert an output signal from the capacitance sensing circuit into a digital value, and a calculating circuit to determine a touch using the converted digital value.

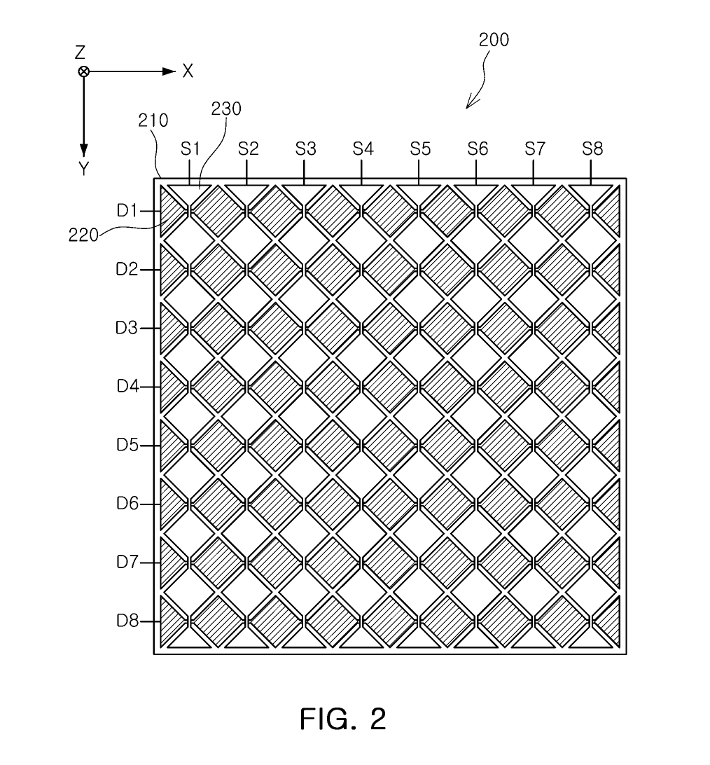

FIG. 2 is a view of a panel part included in a touch sensing device according to an embodiment of the present invention.

Referring to FIG. 2, the panel part 200 according to the embodiment includes a substrate 210 and a plurality of electrodes 220 and 230 provided on the substrate 210. Although not shown in FIG. 2, each of the plurality of electrodes 220 and 230 may be electrically connected to a wiring pattern on a circuit board attached to one end of the substrate 210 through wirings and a bonding pad. The circuit board may have a controller integrated circuit mounted thereon so as to detect a sensing signal generated in the plurality of electrodes 220 and 230, and may determined a touch based on the detected sensing signal.

In the case of the touchscreen apparatus, the substrate 210 may be a transparent substrate on which the plurality of electrodes 220 and 230 are to be formed, which may be formed of a plastic material such as polyimide (PI), polymethylmethacrylate (PMMA), polyethyleneterephthalate (PET), or polycarbonate (PC), or tempered glass. In addition to the region on which the plurality of electrodes 220 and 230 are formed, the substrate 210 may have a printed region formed thereon, which includes wirings connecting the plurality of electrodes 220 and 230 and hides the wirings typically made of an opaque metal.

The plurality of electrodes 220 and 230 may be provided on one surface or both surfaces of the substrate 210, and be formed of indium tin oxide (ITO), indium zinc oxide (IZO), zinc oxide (ZnO), carbon nanotubes (CNT), a graphene based material, or the like, that is transparent and has electrical conductivity in the case of the touchscreen apparatus. Although the plurality of electrodes 220 and 230 are shown to have a lozenge- or diamond-shaped pattern in FIG. 2, it is obvious that the plurality of electrodes 220 and 230 may have a variety of polygonal shapes such as rectangle and triangle.

The plurality of electrodes 220 and 230 may include first electrodes 220 extending in the X axial direction, and second electrodes 230 extending in the Y axial direction. The first electrodes 220 and the second electrodes 230 may be provided on both surfaces of the substrate 210 or may be provided on different substrates 210 such that they may intersect with each other. When the first electrodes 220 and the second electrodes 230 are provided on one surface of the substrate 210, a predetermined insulating layer may be partially formed on intersections between the first electrodes 220 and the second electrodes 230.

The device, electrically connected to the plurality of electrodes 220 and 230 to sense a touch, detects a change in capacitance generated in the plurality of electrodes 220 and 230 by a touch and senses the touch based on the detected change. The first electrodes 220 may be connected to channels referred to as D1 to D8 in the controller integrated circuit to receive predetermined driving signals, and the second electrodes 230 may be connected to channels referred to as S1 to S8 to receive predetermined driving signals. In addition, the channels S1 to S8 may be used when the controller integrated circuit detects sensing signals. Here, the controller integrated circuit may detect a change in mutual-capacitance between the first electrodes 220 and the second electrodes 230, and the self-capacitance generated in the second electrodes 230 themselves, as a sensing signal. In this case, driving signals may be sequentially applied to the first electrodes 220 and then to the second electrodes 230, and changes in capacitance may be detected in the second electrodes 230 simultaneously.

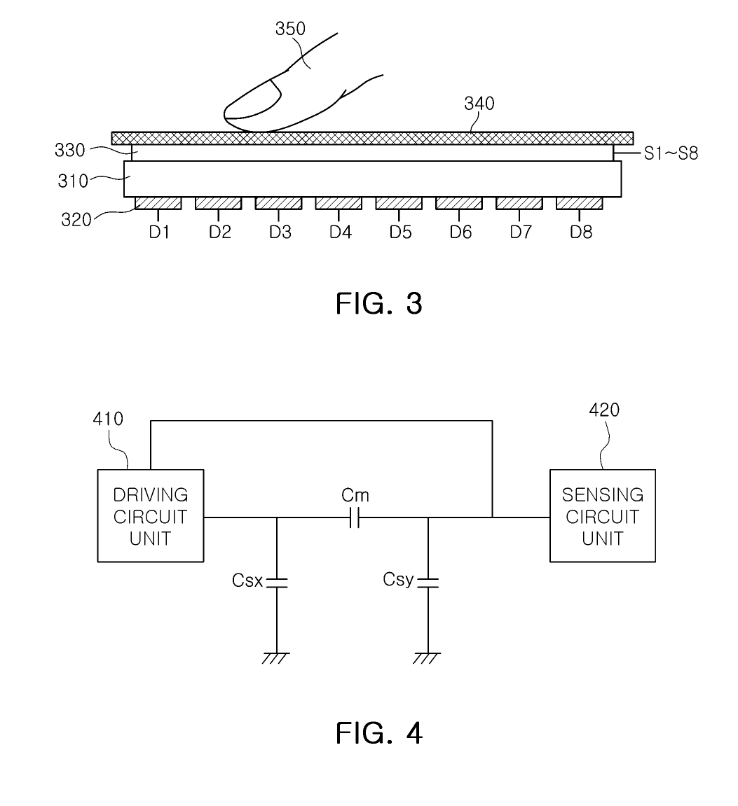

FIG. 3 is a cross-sectional view of the panel part shown in FIG. 2. FIG. 3 is a cross-sectional view of the panel part 200 shown in FIG. 2 in the y-z plane, in which the panel part 200 may further include a cover lens 340, in addition to the substrate 310, and the plurality of electrodes 320 and 330 described above. The cover lens 340 is provided on the second electrodes 330 used in detecting sensing signals, to receive a touch from a contacting object 350 such as a finger.

When driving signals are sequentially applied to the first electrodes 320 though the channels D1 to D8, mutual-capacitance is generated between the first electrode 320, to which the driving signals are applied, and the second electrodes 330. When the driving signals are sequentially applied to the first electrodes 320, a change is made in the mutual-capacitance generated between the first electrode 320, which the contacting object 350 comes into contact with, and the second electrodes 330. The change in the mutual-capacitance may be proportional to the area of the region on which the first electrodes 320, which the contacting object 350 comes into contact with and the driving signals are applied to, and the second electrodes 330 overlap one another. In FIG. 3, the mutual-capacitance generated between the first electrodes 320 connected to channels D2 and D3, respectively, and the second electrodes 330 is influenced by the contacting object 350.

Likewise, when driving signals are sequentially applied to the second electrodes 330 through the channels S1 to S8, self-capacitance is generated in the second electrodes 330 to which the driving signals are applied, such that a change in the self-capacitance is made between the regions, which the contacting object 350 comes into contact with, and the adjacent second electrodes 330.

FIG. 4 is a block diagram of a touch sensing device according to an embodiment of the present invention. Referring to FIG. 4, the touch sensing device according to the embodiment of the present invention may include a driving circuit unit 410 and a sensing circuit unit 420. Between the driving circuit 410 and the sensing circuit unit 420, capacitors Cm, Csx, Csy in which capacitance to be measure is generated may be disposed.

The capacitor Csx may be disposed between one terminal of the capacitor Cm and the ground, and the capacitor Csy may be disposed between the other terminal of the capacitor Cm and the ground.

The capacitor Cm is a node capacitor in which electrical charges are charged and discharged as the mutual-changes in capacitance generated among a plurality of electrodes included in a capacitive touchscreen. The capacitors Csx and Csy are a self-capacitors in which electrical charges are charged and discharged as the changes in self-capacitance generated among a plurality of electrodes included in a capacitive touchscreen. Here, the capacitor Csx may be formed in the first electrodes extending on the X-axis in FIG. 2, and the capacitor Csy may be formed in the second electrodes extending on the Y-axis in FIG. 2. The touch sensing device according to the embodiment uses the node capacitor Cm and the self-capacitor Csy to detect changes in the mutual-capacitance and self-capacitance, which will be described in detail.

The driving circuit unit 410 may generate a predetermined driving signal for charging the electrical charges so as to supply the generated driving signal to the node capacitor Cm and the self-capacitor Csy. The driving signal may be a square wave signal having a pulse form, and have a predetermined frequency. Here, the driving signal supplied to the node capacitor Cm and one supplied to the self-capacitor Csy may be supplied in different periods. For example, during a period for detecting a change in the mutual-capacitance, a driving signal may be applied to the node capacitor Cm but may not be applied to the self-capacitor Csy. During a period for detecting a change in the self-capacitance, in contrast, a driving signal may be applied to the self-capacitor Csy but may not be applied to the node capacitor Cm. In this regard, the driving signals applied to the node capacitor Cm and the self-capacitor Csy may be the same driving signal or may be different driving signal having different sizes, duties, and frequencies.

The sensing circuit unit 420 includes at least one feedback capacitor charged and discharged by receiving the electrical charges charged in the node capacitor Cm and the self-capacitor Csy. The sensing circuit unit 420 generates an output signal, an analog signal, from the electrical charges charged in/discharged from the feedback capacitor.

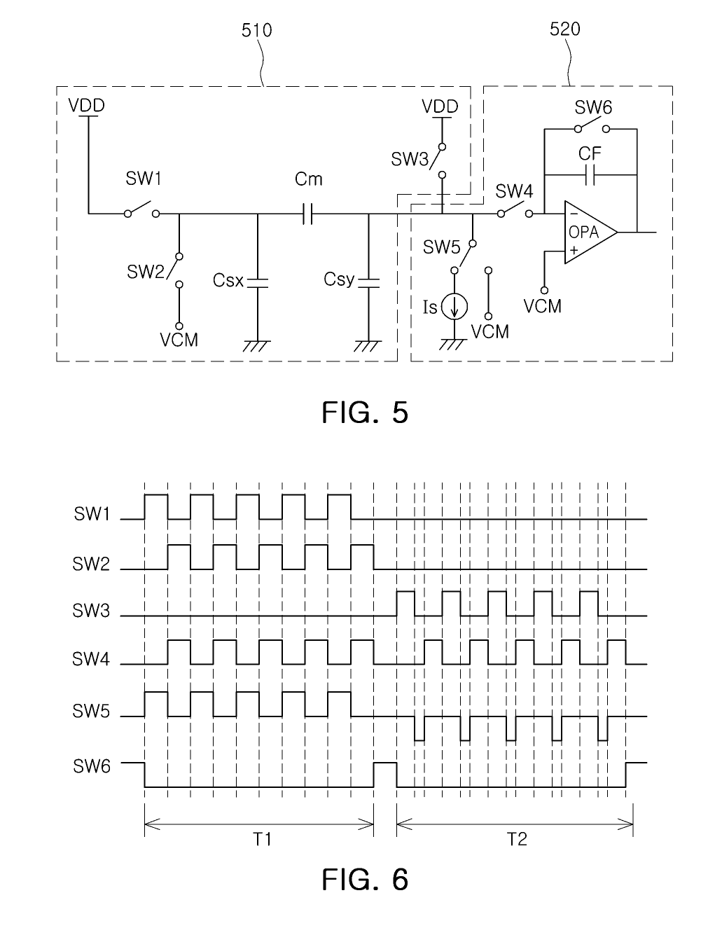

FIG. 5 is a circuit diagram of a touch sensing device according to an embodiment of the present invention. Referring to FIG. 5, the touch sensing device according to the embodiment of the present invention may include a driving circuit unit 510 and a sensing circuit unit 520. The driving circuit unit 510, the sensing circuit unit 520 and the capacitor Cm, Csx and Csy depicted in FIG. 5 are identical to those shown in FIG. 4; and, therefore, the descriptions thereon will not be repeated.

The driving circuit unit 510 includes switches SW1, SW2 and SW3. The switch SW1 is disposed between a supply voltage terminal VDD and one terminal of the node capacitor Cm, the switch SW2 is disposed between a common mode voltage VCM terminal and the one terminal of the node capacitor Cm, and the switch SW3 is disposed between the other terminal of capacitor Cm and the supply voltage terminal VDD. Here, the connection node between the capacitor Cm and the capacitor Csx corresponds to the first electrodes in FIG. 2, and the connection node between the capacitor Cm and the capacitor Csy corresponds to the second electrodes in FIG. 2.

The sensing circuit unit 520 may include an operational amplifier OPA, a feedback capacitor CF, switches SW4, SW5 and SW6, and a current source Is. The non-inverted input of the operational amplifier is connected to the common mode voltage VCM terminal, the switch SW4 is disposed between the inverted input of the operational amplifier OPA and the other terminal of the node capacitor Cm, the inverted input and the output of the operational amplifier OPA are connected to each other via the feedback capacitor CF, and the switch SW6 is disposed in parallel with the feedback capacitor CF. The switch SW5 is a three-terminal switch, one terminal of which is connected to the other terminal of the node capacitor, and the other terminals of which may be connected to the current source Is or the common mode voltage VCM terminal, or may be floated. In the present embodiment, the common mode voltage VCM may have, but is not limited to, a middle level of the supply voltage VDD, but may have a ground GND level.

FIG. 6 is a graph illustrating clock signals applied to a switch included in a touch sensing device according to an embodiment of the present invention. When a clock signal having a high level is applied to the switches SW1 to SW4 and SW6, the switches are turned-on, while when a clock signal having a low level is applied to the switches SW1 to SW4 and SW6, the switches are turned-off. When a signal having a high level is applied to the switch SW5, the switch SW5 is connected to the common mode voltage VCM terminal, when a clock signal having a low level is applied to the switch SW5, the switch SW5 is connected to the current source Is, and when a clock signal having a middle level is applied to the switch SW5, the switch SW5 is turned-off. In the following, the operation of the touch sensing device according to an embodiment of the present invention will be described in detail with reference to FIGS. 5 and 6.

During T1 duration, the switches SW1 and SW2 are switched according to the complementary clock signals having the phase difference of 180 degree, so that they provide the node capacitor Cm with driving signals having a predetermined frequency. Likewise, the switches SW4 and SW5 are switched according to the complementary clock signals having the phase difference of 180 degree. The electrical charges charged in the node capacitor are sequentially transmitted to the operational amplifier OPA and the feedback capacitor CF, according to the complementary switching of the switches SW4 and SW5, and integrated. Here, during the duration T1, the clock signal provided to the switch SW4 may be the same with the clock signal provided to the switch SW2, and the clock signal provided to the switch SW5 may be the same with clock signal provided to the switch SW1. During the duration T1, the electrical charges charged in/discharged from the node capacitor Cm are integrated in the operational amplifier OPA and the feedback capacitor CF, such that a change in the mutual capacitance can be detected.

Between the T1 duration and the T2 duration, the switch SW6 is turned on, such that the output voltage of the operational amplifier OPA is reset. During the T2 duration, the switch SW3 is switched to provide a predetermined driving signal to the self-capacitor Csy, such that the self-capacitor is charged according to the driving signal. Right after the switch SW3 is turned off, the switch SW5 is connected to the current source Is, and the current source Is discharges a portion of the electrical charges charged in the self-capacitor Csy. After a predetermined time has elapsed since the switch SW5 is turned off, switch SW4 is turned on, such that the electrical charges charged in the self-capacitor Csy are transmitted to the operational amplifier OPA and the feedback capacitor CF and integrated.

In general, a self-capacitor has several tens to hundred times larger capacitance than a node capacitor. Therefore, if the electrical charges charged in the self-capacitor are directly integrated, the capacitance of the feedback capacitor should be increased according to the capacitance of the self-capacitor. According to the embodiment, the capacitance of the feedback capacitor CF may be significantly reduced by discharging a portion of the electrical charges charged in the self-capacitor through the current source Is before the charges are integrated.

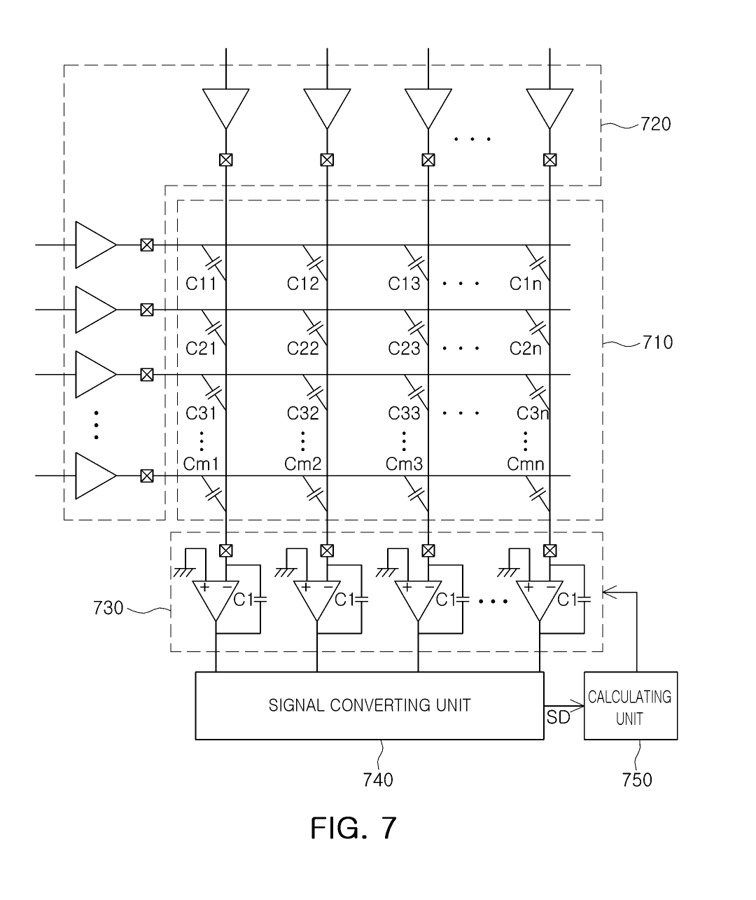

FIG. 7 is a view schematically illustrating a touchscreen apparatus including a touch sensing device according to an embodiment of the present invention.

Referring to FIG. 7, the touchscreen apparatus according to the present embodiment may include a panel unit 710, a driving circuit unit 720, a sensing circuit unit 730, a signal converting unit 740, and an calculation unit 750. The panel unit 710 may include a plurality of first electrodes extending in a first axial direction (that is, a horizontal direction of FIG. 7), and a plurality of second electrodes extending in a second axial direction (that is, a vertical direction of FIG. 7). As described above, node capacitors C11 to Cmn are disposed at points of intersection between the first electrodes and the second electrodes. The driving circuit unit 720, the sensing circuit unit 730, the signal converting unit 740, and the calculating unit 750 may be implemented as a single integrated circuit (IC).

The driving circuit unit 720 may apply predetermined driving signals to the first electrodes of the panel unit 510. The driving signals may be square wave signals, sine wave signals, triangle wave signals or the like having a predetermined period and amplitude, and may be sequentially applied to each of the plurality of first electrodes and then to each of the plurality of second electrodes. That is, a period for detecting a change in the mutual capacitance and one for detecting a change in the self-capacitance may be different. Although circuits for generating and applying the driving signals are individually connected to the plurality of first and second electrodes in FIG. 7, a single driving signal generating circuit may use a switching circuit to apply the driving signals to each of the plurality of first electrodes.

The sensing circuit unit 730 is connected to the second electrode, to detect a change in the mutual-capacitance and that in the self-capacitance. The sensing circuit unit 730 includes an integrating circuit to sense a change in capacitance. The integrating circuit may include at least one operational amplifier and a capacitor C1 having a predetermined degree of capacitance, and the operational amplifiers have an inverting input connected to the second electrode to convert the change in capacitance into analog signals such as voltage signals or the like, and then output the analog signals. The sensing circuit 730 may detect a change in capacitance from the plurality of second electrodes simultaneously; the number of the integrating circuit may be equal to the number n of the second electrodes.

The signal converting unit 740 may generate a digital signal S_{D} from an analog signal generated by the integrating circuit. For example, the signal converting unit 740 may include a time to digital converter (TDC) circuit measuring a time in which the analog signal output in a voltage form output from the sensing circuit unit 730 reach a predetermined reference voltage level and converting the measured time into the digital signal S_{D}, or an analog to digital converter (ADC) circuit measuring an amount by which a level of the analog signal output from the sensing circuit unit 730 is changed for a predetermined time and converting the change amount into the digital signal S_{D}.

The calculating unit 750 may determine a touch applied to the panel unit 710 using the digital signal S_{D}. As an example, the calculating unit 750 may determine the number, coordinates, gesture operations or the like of a touch applied to the panel unit 710.

As set forth above, according to embodiments of the present invention, changes in self-capacitance and mutual capacitance can be selectively detected. Further, the capacity of a feedback capacitor detecting changes in capacitance is reduces, such that the size and volume of the device can be reduced.

While the present invention has been shown and described in connection with the embodiments, it will be apparent to those skilled in the art that modifications and variations can be made without departing from the spirit and scope of the invention as defined by the appended claims.

What is claimed is:

1. A touch sensing device comprising:
a node capacitor;
a self-capacitor disposed between one terminal of the node capacitor and a ground;
a driving circuit unit applying predetermined driving signals to the node capacitor and the self-capacitor; and
a sensing circuit unit integrating electrical charges charged in the node capacitor and the self-capacitor,
wherein the driving circuit unit applies the driving signals to the node capacitor and the self-capacitor in different periods.

2. The device of claim 1, wherein the driving circuit unit includes:
a first switch disposed between a supply voltage terminal and the other terminal of the node capacitor;
a second switch disposed between the other terminal of the node capacitor and the ground; and
a third switch disposed between a connection node of the node capacitor and the self-capacitor, and the supply voltage terminal.

3. The device of claim 2, wherein the first and second switches and the third switch operate during different periods.

4. The device of claim 2, wherein the first and second switches operate according to clock signals having a phase difference of 180 degree.

5. The device of claim 1, wherein the sensing circuit unit discharges a portion of an electrical charge charged in the self-capacitor and then integrates the remainder of the charge.

6. The device of claim 2, wherein the sensing circuit unit includes:
an integrating circuit including an operational amplifier having a non-inverted terminal connected to the ground, and a feedback capacitor disposed between an output terminal and an inverted terminal of the operational amplifier;
a fourth switch disposed between the connection node of the node capacitor and the self-capacitor, and the inverted terminal of the operational amplifier;
a fifth switch having one terminal connected to the connection node of the node capacitor and the self-capacitor; and
a current source, wherein the other terminal of the fifth switch is connected to the current source or to the ground, or is floated.

7. The device of claim 1, wherein the node capacitor is formed at an intersection between electrodes of a capacitive type touchscreen panel, and wherein the self-capacitor is formed by the electrodes of the touchscreen panel.

8. A touchscreen apparatus comprising:
a plurality of first electrodes extending in a first axial direction;
a plurality of second electrodes extending in a second axial direction perpendicular to the first axial direction so as to form a plurality of intersections; and
a control unit applying predetermined first driving signals to the plurality of first electrodes to detect changes in mutual-capacitance generated in the plurality of intersections, and applying predetermined second driving signals to the plurality of second electrodes to detect changes in self-capacitance generated in the plurality of second electrodes themselves, wherein the control unit detects changes in the mutual-capacitance and the self-capacitance indifferent periods.

9. The apparatus of claim 8, wherein the control unit includes: a driving circuit unit applying predetermined driving signals to each of the pluralities of first and second electrodes; and
a sensing circuit unit connected to the plurality of second electrodes, the sensing circuit unit detecting changes in mutual-capacitance generated in a plurality of intersections between the pluralities of first and second electrodes, and detecting changes in self-capacitance generated in the plurality of second electrodes.

10. The apparatus of claim 9, wherein the driving circuit unit applies the driving signals to the pluralities of first and second electrodes during different periods.

11. The apparatus of claim 9, wherein the driving circuit unit applies different driving signals to the pluralities of first and second electrodes.

12. The apparatus of claim 9, wherein the sensing circuit unit integrates the mutual and self capacitance to create an analog signal.

13. The apparatus of claim 12, wherein the sensing circuit unit discharges a portion of the self-capacitance and then integrates the remainder of the capacitance.

14. The apparatus of claim 9, wherein the control unit further includes:
a signal converting unit converting an output signal from the sensing circuit unit into a digital signal; and
a calculating unit determining a touch based on the digital signal.

15. The apparatus of claim 14, wherein the calculation unit determines at least one coordinate of coordinates of the touch, a gesture operation and the number of touch.
